(19) United States
(12) Patent Application Publication
(10) Pub. No.: US 2024/0354460 A1
(43) Pub. Date: Oct. 24, 2024

(54) BUCKLING-RESTRAINED BRACE OUT-OF-PLANE STABILITY DESIGN METHOD CONSIDERING BIDIRECTIONAL SEISMIC ACTION

(71) Applicants: SOUTH CHINA UNIVERSITY OF TECHNOLOGY, Guangzhou (CN); BEIJING BRACE DAMPING ENGINEERING TECHNOLOGY CO., LTD, Beijing (CN)

(72) Inventors: Junxian ZHAO, Guangzhou (CN); Junming LI, Guangzhou (CN); Wei HAN, Guangzhou (CN); Yun ZHOU, Guangzhou (CN)

(73) Assignees: SOUTH CHINA UNIVERSITY OF TECHNOLOGY, Guangzhou (CN); BEIJING BRACE DAMPING ENGINEERING TECHNOLOGY CO., LTD, Beijing (CN)

(21) Appl. No.: 18/760,001

(22) Filed: Jun. 30, 2024

Related U.S. Application Data
(63) Continuation-in-part of application No. 18/278,847, filed on Aug. 25, 2023.

(30) Foreign Application Priority Data
Dec. 2, 2022 (CN) 202211625330.0

(51) Int. Cl. G06F 30/13; E04H 9/02

(52) U.S. Cl. CPC G06F 30/13; E04H 9/0237

(57) ABSTRACT

The present invention provides a buckling-restrained brace out-of-plane stability design method considering a bidirectional seismic action. The method includes the following steps: determining geometric dimensions of a buckling-restrained brace and a gusset plate and a target out-of-plane displacement angle; calculating resistance parameters and stiffness parameters, the resistance parameters including a yield axial force of the gusset plate, and the stiffness parameters including rotational stiffness of the gusset plate, an ultimate bending moment of the gusset plate, and flexural stiffness of connecting segments of the buckling-restrained brace; and calculating an out-of-plane elastic buckling critical force of the buckling-restrained brace; calculating a trigger eccentricity, checking whether out-of-plane stability of the brace is met, if the out-of-plane stability of the brace is met, determining that a designed buckling-restrained brace damping system is capable of ensuring the out-of-plane stability under the bidirectional seismic action.

### CROSS-REFERENCE TO RELATED APPLICATIONS

This application is a continuation-in-part of and claims the priority benefit of U.S. patent application Ser. No. 18/278,847, filed on Aug. 25, 2023, now pending. The prior U.S. patent application Ser. No. 18/278,847 is a 371 of International PCT application serial no. PCT/CN2023/083972, filed on Mar. 27, 2023, which claims the priority benefit of China Patent Application No. 202211625330.0, filed on Dec. 2, 2022. The entirety of each of the above-mentioned patent applications is hereby incorporated by reference herein and made a part of this specification.

### BACKGROUND

### Technical Field

The present invention belongs to the technical field of seismic design, and particularly relates to a herringbone buckling-restrained brace out-of-plane stability design method considering a bidirectional seismic action.

### Description of Related Art

A buckling-restrained brace is a form of bracing (FIG. 1) with dual functions as an ordinary brace and a metal energy dissipation damper, and has become an effective means for structural damping control and improvement of structural seismic performance in the past decade or so. The key to achieving energy dissipation of the buckling-restrained brace lies in how to solve the problem of buckling of the brace under pressure, and then play the function of the buckling-restrained brace as a structural fuse. Typical buckling failure modes of the buckling-restrained brace are summarized into four types: global buckling, local buckling, in-plane buckling of a core overhang segment, and out-of-plane buckling of the core overhang segment and gusset plates connected thereto. After decades of development, more mature design methods have been formed for the first three failure modes at home and abroad, and are written into relevant standards and specifications. An overhang segment (that is, a transition segment and a connecting segment shown in FIG. 1) of the buckling-restrained brace and the gusset plates connected thereto have low out-of-plane flexural stiffness and are not restrained by a restraining unit, thereby being prone to out-of-plane buckling. Most of the existing studies on buckling-restrained brace damping technology are based on a plane frame theory, that is, only the influence on the bracing performance by a unidirectional seismic action borne by the frame in an in-plane direction is considered. However, relevant studies have shown that the buckling-restrained brace is likely to cause significant bidirectional deformation of a structural floor under the bidirectional seismic action, and then geometric and physical boundary conditions of both ends of the buckling-restrained brace are changed, which is significantly different from existing design theories established by considering only the unidirectional seismic action, so the buckling-restrained brace is more susceptible to out-of-plane instability damage than when subjected to the unidirectional seismic action only. In view of the randomness, multi-directionality and other characteristics of the seismic action, it is necessary to further develop a buckling-restrained brace out-of-plane stability design theory considering the bidirectional seismic action.

As for buckling-restrained brace out-of-plane stability design methods, two design ideas are mainly adopted at home and abroad: “separated” and “integral”.

According to the “separated” design method, a gusset plate is isolated from a buckling-restrained brace and a subframe, a supporting axial force after isolation acts on the gusset plate, and the batten out-of-plane stability bearing capacity between a batten between an effective section of the gusset plate and a beam column is calculated based on a column-bar theory, ignoring the interaction between the gusset plate and the brace. This method has the advantages of simple mechanical model and easy calculation, but completely cuts off the coupling between the bidirectional deformation of a floor and the out-of-plane deformation of a connecting segment of the buckling-restrained brace and the gusset plate and internal forces, and may not consider the influence of bidirectional deformation on the out-of-plane stability of the buckling-restrained brace.

According to the “integral” design method, the gusset plate, an overhang segment of the buckling-restrained brace, a restrained segment of the buckling-restrained brace, and even frame members (beams and columns) connected to the gusset plate are regarded as a subsystem, out-of-plane stability of the subsystem under an in-plane unidirectional seismic action is searched, and a plastic hinge theory model (shown in FIG. 2) and a bending moment transfer theory model (shown in FIG. 3) are established. Although the above models have well considered the influence of the out-of-plane stiffness of the subframe and the gusset plate on the out-of-plane stability of the buckling-restrained brace, they are still essentially plane theories based on the unidirectional seismic action and fail to consider the influence of bidirectional floor deformation caused by the bidirectional seismic action on the out-of-plane stability of the buckling-restrained brace in essence. Moreover, too many parameters are considered in the design method, so that the design is very complicated and not convenient for practical application.

### SUMMARY

In order to solve the problem that an existing buckling-restrained brace out-of-plane stability design method may not consider the influence of a bidirectional seismic action, the present invention provides a buckling-restrained brace out-of-plane stability practical design method considering a bidirectional seismic action based on a common herringbone brace layout form at home and abroad, so as to break through the theoretical limitation that an existing braced frame design may only consider a unidirectional seismic action.

In order to achieve the object of the present invention, the present invention provides a buckling-restrained brace out-of-plane stability design method considering a bidirectional seismic action, wherein a buckling-restrained brace is used in a buckling-restrained brace damping system, the buckling-restrained brace damping system includes a buckling-restrained brace subsystem, the buckling-restrained brace subsystem includes the buckling-restrained brace and a gusset plate, both ends of the buckling-restrained brace are connected to a beam end and a column end via the gusset plate, respectively. The method includes the following steps:
step 1: providing a designed buckling-restrained brace subsystem including a frame, a buckling-restrained brace and two gusset plates, the frame including beams and columns, the two gusset plates fixed to the beams, and two sides of the buckling-restrained brace inserted into the two gusset plates, determining geometric dimensions of the buckling-restrained brace and each of the two gusset plates, and a target out-of-plane displacement angle θ;
step 2: calculating resistance parameters and stiffness parameters, the resistance parameters including a yield axial force P_{gy} of the each of the two gusset plates, and the stiffness parameters including a rotational stiffness K_{Rg} of the each of the two gusset plates, an ultimate bending moment M_{gu} of the each of the two gusset plates, and flexural stiffnesses of connecting segments of the buckling-restrained brace; wherein each of the two gusset plates includes a horizontal side rib and a vertical side rib, and for the yield axial force of the each of the two gusset plates, the yield axial force of the each of the two gusset plates being calculated according to a 30° angle effective section of the each of the two gusset plates, wherein a connecting line between an intersection joint of the horizontal side rib and a column side and an intersection joint of the vertical side rib and a beam side is an equivalent flexural section width b_{M}, an effective section width bₑ is obtained by inward extending two endpoints of an abutting surface width b_{J} of an unrestrained side of the each of the two gusset plates to a straight line where equivalent flexural section width b_{M} by is located at an angle 30° deviated from a central rib, and the yield axial force P_{gy} of the each of the two gusset plates is calculated based on the effective section width bₑ; a shear deformation of the each of the two gusset plates being ignored, and the rotational stiffness K_{Rg} of the each of the two gusset plates and the ultimate bending moment M_{gu} of the each of the two gusset plates being obtained based on a rigid body spring model;
step 3: calculating an out-of-plane elastic buckling critical force P_{cr} of the buckling-restrained brace; and
step 4: calculating a trigger eccentricity eₜᵣ, checking whether an out-of-plane stability of the buckling-restrained brace is met based on the trigger eccentricity eₜᵣ, the out-of-plane elastic buckling critical force P_{cr} of the buckling-restrained brace, the ultimate bending moment M_{gu} of the each of the two gusset plates, and a maximum axial pressure Nᵤ of the buckling-restrained brace, an expression for checking the out-of-plane stability of the buckling-restrained brace is:

$${P}_{lim} = \frac{{P}_{gy}}{2} + \frac{{P}_{cr}}{2} + \frac{{P}_{gy} {P}_{cr} {e}_{tr}}{2 {M}_{gu}} - \sqrt{{( \frac{{P}_{gy}}{2} + \frac{{P}_{cr}}{2} + \frac{{P}_{gy} {P}_{cr} {e}_{tr}}{2 {M}_{gu}} )}^{2} - {P}_{gy} {P}_{cr}} > {N}_{u}$$

wherein Pₗᵢₘ denotes an out-of-plane ultimate load of the buckling-restrained brace, P_{gy} denotes the yield axial force of the 30° angle effective section of the each of the two gusset plates, and the maximum axial pressure Nᵤ of the buckling-restrained brace, the ultimate bending moment M_{gu} of the each of the two gusset plates, the yield axial force P_{gy} of the 30° angle effective section of the each of the two gusset plates, the out-of-plane elastic buckling critical force P_{cr} of the buckling-restrained brace, and the trigger eccentricity eₜᵣ related to the geometric dimensions of the buckling-restrained brace and the each of the two gusset plates;
if the out-of-plane stability of the buckling-restrained brace is met, determining that the buckling-restrained brace damping system including the buckling-restrained brace subsystem which is constructed based on the parameters obtained by the above-mentioned steps is capable of ensuring the out-of-plane stability of the buckling-restrained brace under the bidirectional seismic action, and constructing a building structure by providing the designed buckling-restrained brace subsystem including the frame, the buckling-restrained brace and the two gusset plates, the frame including the beams and the columns, the two gusset plates fixed to the beams, and the two sides of the buckling-restrained brace inserted into the two gusset plates based on the designed buckling-restrained brace subsystem in the step 1; and if the out-of-plane stability of the buckling-restrained brace is not met, determining that the designed buckling-restrained brace damping system is to suffer out-of-plane instability under the bidirectional seismic action, and returning to step 1 to re-determine the geometric dimensions of the buckling-restrained brace and each of the two gusset plates and the target out-of-plane displacement angle θ, so as to at last construct the buckling-restrained brace damping system which is capable of ensuring the out-of-plane stability of the buckling-restrained brace under the bidirectional seismic action.

Further, in step 2, a calculation formula of the yield axial force of the gusset plate is:

$${P}_{gy} = {b}_{e} {t}_{g} {f}_{gy}$$

where P_{gy} denotes the yield axial force of the 30° angle effective section of the gusset plate, bₑ denotes a width of an effective section formed according to a 30° diffusion line of the gusset plate, t_{g} denotes a thickness of the gusset plate, and f_{gy} denotes the yield strength of the gusset plate.

Further, in step 2, with the shear deformation of the gusset plate ignored, the gusset plate is divided into a plurality of triangle elements according to possible yield lines of the gusset plate, wherein a rotation spring generated at a tail of a part where the buckling-restrained brace is inserted into the gusset plate is defined as a joint \textcircled{3}, a tail endpoint of the horizontal side rib of the gusset plate is defined as a joint \textcircled{4}, a tail endpoint of the vertical side rib of the gusset plate is defined as a joint \textcircled{2}, an intersection of the vertical side rib and the beam side is defined as a joint \textcircled{5}, an intersection of the horizontal side rib and the column side is defined as a joint \textcircled{6}, an intersection of the beam side and the column side is defined as a joint \textcircled{7}, and a connecting edge between the buckling-restrained brace and the gusset plate is defined as a joint \textcircled{1}; connecting lines between the joint \textcircled{3} with the joint \textcircled{1}, the joint \textcircled{2}, the joint \textcircled{4}, the joint \textcircled{5}, the joint \textcircled{6} and the joint \textcircled{7} divide the gusset plate into the plurality of triangle elements, and connecting edges between every two adjacent triangular elements of the triangle elements are the possible yield lines of the gusset plate; each of the triangle elements is regarded as a rigid body, and an out-of-plane concentrated force N acts on the joint \textcircled{1}, wherein a connecting line between the joints \textcircled{1} and \textcircled{2}, the connecting line between the joints \textcircled{1} and \textcircled{3}, and the connecting line between the joints \textcircled{2} and \textcircled{3} are defined to form a triangle element A; a connecting line between the joints \textcircled{1} and \textcircled{4}, the connecting line between the joints \textcircled{1} and \textcircled{3}, and the connecting line between the joints \textcircled{3} and \textcircled{4} are defined to form a triangle element B; a connecting line between the joints \textcircled{2} and \textcircled{5}, the connecting line between the joints \textcircled{3} and \textcircled{5}, and the connecting line between the joints \textcircled{2} and \textcircled{3} are defined to form a triangle element C; the connecting line between the joints \textcircled{3} and \textcircled{4}, the connecting line between the joints \textcircled{3} and \textcircled{6}, and a connecting line between the joints \textcircled{4} and \textcircled{6} are defined to form a triangle element D; and rotational stiffness of the joint \textcircled{3} of the gusset plate is considered to be related only to the triangle elements A, B, C and D, thereby obtaining:

$${k}_{AB} = \frac{{Et}_{g}^{3}}{12 ( 1 - {v}^{2} )} \cdot \frac{2 {l}_{13}}{{}_{AB} {h}_{A} + {}_{AB} {h}_{B}} \qquad ( 2 )$$

$${k}_{AC} = \frac{{Et}_{g}^{3}}{12 ( 1 - {v}^{2} )} \cdot \frac{2 {l}_{23}}{{}_{AC} {h}_{A} + {}_{AC} {h}_{C}} \qquad ( 3 )$$

$${k}_{BD} = \frac{{Et}_{g}^{3}}{12 ( 1 - {v}^{2} )} \cdot \frac{2 {l}_{34}}{{}_{BD} {h}_{B} + {}_{BD} {h}_{D}} \qquad ( 4 )$$

$${}_{AC} {K}_{11} = \frac{{k}_{AC}}{{}_{AC} {h}_{A}^{2}} \qquad ( 5 )$$

$${}_{BD} {K}_{11} = \frac{{k}_{BD}}{{}_{BD} {h}_{B}^{2}} \qquad ( 6 )$$

$${}_{AB} {K}_{11} = {k}_{AB} \cdot {( \frac{\sqrt{{l}_{23}^{2} - {}_{AB} {h}_{A}^{2}}}{{l}_{13} \cdot {}_{AB} {h}_{A}} + \frac{\sqrt{{l}_{34}^{2} - {}_{AB} {h}_{B}^{2}}}{{l}_{13} \cdot {}_{AB} {h}_{B}} )}^{2} \qquad ( 7 )$$

where k_{AB}, k_{AC}, and k_{BD} denote rotation spring stiffnesses between the triangle elements A and B, the triangle elements A and C, and the triangle elements B and D respectively, E denotes an elastic modulus of a gusset plate material, t_{g} denotes the thickness of the gusset plate, ν denotes a Poisson's ratio of the gusset plate, _{AB}h_{A} and _{AB}h_{B} denote distances from vertexes of the triangle elements A and B to an AB yield line \textcircled{1}\textcircled{3} respectively, _{AC}h_{A} and _{AC}h_{C} denote distances from vertexes of the triangle elements A and C to an AC yield line \textcircled{2}\textcircled{3} respectively, _{BD}h_{B} and _{BD}h_{D} denote distances from vertexes of the triangle elements B and D to a BD yield line \textcircled{3}\textcircled{4} respectively, _{AB}K₁₁, _{AC}K₁₁, and _{BD}K₁₁ denote out-of-plane translational stiffnesses of the joint \textcircled{1} provided by the triangle elements A and B, the triangle elements A and C, and the triangle elements B and D respectively, and l₁₃, l₃₄, and l₂₃ denote distances between the joints \textcircled{1} and \textcircled{3}, the joints \textcircled{3} and \textcircled{4}, and the joints \textcircled{2} and \textcircled{3} respectively.

Further, in step 2, a calculation formula of the rotational stiffness K_{Rg} of the gusset plate is:

$${K}_{Rg} = ( {}_{AB} {K}_{11} + {}_{AC} {K}_{11} + {}_{BD} {K}_{11} ) {l}_{13}^{2} .$$

Further, a calculation formula of the ultimate bending moment M_{gu} of the gusset plate is:

$${M}_{gu} = \frac{{f}_{gy} {t}_{g}^{2}}{4} \cdot {l}_{13} \cdot ( \frac{\sqrt{{l}_{23}^{2} - {}_{AB} {h}_{A}^{2}}}{{}_{AB} {h}_{A}} + \frac{\sqrt{{l}_{34}^{2} - {}_{AB} {h}_{B}^{2}}}{{}_{AB} {h}_{B}} + \frac{{l}_{23}}{{}_{AC} {h}_{A}} + \frac{{l}_{34}}{{}_{BD} {h}_{B}} )$$

where f_{gy} denotes the yield strength of the gusset plate.

Further, step 2 further includes calculation of flexural stiffness of a connecting segment, where an inertia moment I in an out-of-plane direction is calculated according to a section of an overhang segment of the buckling-restrained brace, and then multiplied by the elastic modulus E of the gusset plate material to calculate out-of-plane flexural stiffness EI of the overhang segment of the buckling-restrained brace, and the out-of-plane flexural stiffness of the overhang segment of the buckling-restrained brace is used as the flexural stiffness of the connecting segment.

Further, in step 3, a calculation formula of the out-of-plane elastic buckling critical force of the buckling-restrained brace is:

$${P}_{cr} = \frac{( 1 - 2 ξ ) {π}^{2} EI}{{( 2 ξ {l}_{0} )}^{2}} \cdot \frac{{K}_{Rg} ξ {l}_{0} / EI}{{K}_{Rg} ξ {l}_{0} / EI + {π}^{2} / 4}$$

where P_{cr} denotes the out-of-plane elastic buckling critical force of the buckling-restrained brace, l₀ denotes a length of a supporting axis calculated from a center stiffener of the gusset plate, ξ denotes a ratio of a length between one end of a restraining unit and a root of a center rib of a nearest gusset plate along the supporting axis to l₀, and I denotes an out-of-plane inertia moment of an overhang connecting segment of the buckling-restrained brace.

Further, in step 4, a calculation formula of the trigger eccentricity eₜᵣ is:

$${e}_{tr} = \frac{ξθ h}{1 - 2 ξ}$$

where eₜᵣ denotes the trigger eccentricity, h denotes a height of a subframe, θ denotes the target out-of-plane displacement angle, and ξ denotes a ratio of a length between one end of a restraining unit and a root of a center rib of a nearest gusset plate along a supporting axis to l₀.

Further, in step 4, an expression for checking the out-of-plane stability of the brace is:

$${P}_{lim} = \frac{{P}_{gy}}{2} + \frac{{P}_{cr}}{2} + \frac{{P}_{gy} {P}_{cr} {e}_{tr}}{2 {M}_{gu}} - \sqrt{{( \frac{{P}_{gy}}{2} + \frac{{P}_{cr}}{2} + \frac{{P}_{gy} {P}_{cr} {e}_{tr}}{2 {M}_{gu}} )}^{2} - {P}_{gy} {P}_{cr}} > {N}_{u}$$

where Pₗᵢₘ denotes an out-of-plane ultimate load of the buckling-restrained brace, Nᵤ denotes the maximum axial pressure of the buckling-restrained brace, M_{gu} denotes the ultimate bending moment of the gusset plate, P_{gy} denotes the yield axial force of the 30° angle effective section of the gusset plate, P_{cr} denotes the out-of-plane elastic buckling critical force of the buckling-restrained brace, and eₜᵣ denotes the trigger eccentricity.

Further, the application of the design method needs to meet two conditions: the buckling-restrained brace subsystem meets a symmetric analysis model, and a main beam of a frame does not undergo torsion deformation under the seismic action, where in the symmetric analysis model, an upper connecting segment and a lower connecting segment of the buckling-restrained brace are equal in length, the upper connecting segment and the lower connecting segment have equal out-of-plane flexural stiffness, and gusset plates connected up and down have equal out-of-plane rotational stiffness.

Compared with the prior art, the buckling-restrained brace out-of-plane stability practical design method considering the bidirectional seismic action according to the present invention has following advantages:

(1) An out-of-plane ultimate load of the buckling-restrained brace subsystem under the bidirectional seismic action can be accurately predicted, and compared with an existing design method based on the unidirectional seismic action, the method according to the present invention is more scientific and reasonable.

(2) The method is simplified based on a symmetric theoretical model according to the geometric and physical conditions of both ends of the brace, the expression of the calculation formulas is intuitive, and the method is easy for practical engineering application.

(3) The frame beam construction requirements that can avoid considering the influence of out-of-plane deformation of subframes are provided, thereby greatly simplifying key influencing parameters of the out-of-plane stability of the buckling-restrained brace and reducing the hidden danger of engineering safety.

### BRIEF DESCRIPTION OF THE DRAWINGS

In FIG. 1, (a) is a schematic diagram of a buckling-restrained brace, (b) is a section view in a direction A-A of (a), and (c) is a section view in a direction B-B of (a).

FIG. 2 shows conceptual diagrams of a plastic hinge model theory, where (a) is a schematic diagram of a steel frame of a buckling-restrained brace, (b) is a side view of the frame, and (c) is a schematic diagram of an isolated body in a direction A-A in (a).

FIG. 3 shows conceptual diagrams of a bending moment transfer model theory, where (a) is a schematic diagram of a bending moment transfer calculation model, (b) is a deformation diagram of a frame of a buckling-restrained brace under out-of-plane displacement, and (c) is a schematic diagram of bending moment distribution of the frame of the buckling-restrained brace under out-of-plane displacement.

FIG. 4 shows schematic diagrams of an out-of-plane stability calculation model of a buckling-restrained brace subsystem according to the present invention, where (a) is a schematic structural diagram of a buckling-restrained brace subframe, and (b) is a schematic diagram of an isolated body in a direction A-A in (a).

FIG. 5 shows deformation and force analysis under a bidirectional force.

FIG. 6 shows a rigid body spring model, where (a) is a schematic diagram of force and displacement of two adjacent triangle elements, (b) is a schematic plan view of a triangle element without rigid body displacement, and (c) is a view of a section A-A in (a).

FIG. 7 is a schematic diagram of out-of-plane deformation of a gusset plate according to the present invention.

FIG. 8 shows schematic diagrams of a gusset plate equivalent way of calculating a yield axial force of a gusset plate according to the present invention, where (a) is a schematic design diagram of a ribbed gusset plate, and (b) is a schematic diagram of a hypothetical gusset plate.

FIG. 9 is a schematic diagram of calculation of rotational stiffness of a gusset plate according to the present invention.

FIG. 10 is a schematic dimension diagram of a buckling-restrained brace subsystem.

FIG. 11 is a flow diagram of a design method according to the present invention.

FIG. 12 is a schematic diagram of construction requirements of a gusset plate in a herringbone buckling-restrained brace frame adapted to a design method according to the present invention.

FIG. 13 shows result comparison diagrams of existing design methods and a design method according to the present invention, where (a) is a schematic result diagram of an existing separated design method, (b) is a schematic result diagram of an existing integral design method, and (c) is a schematic result diagram of the method according to the present invention.

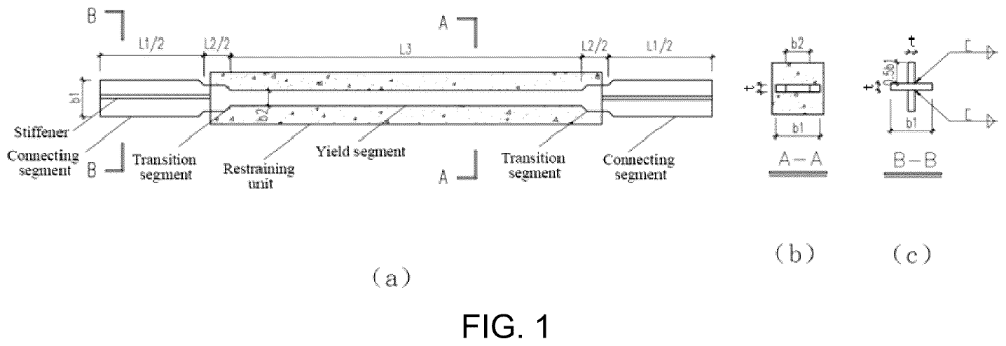

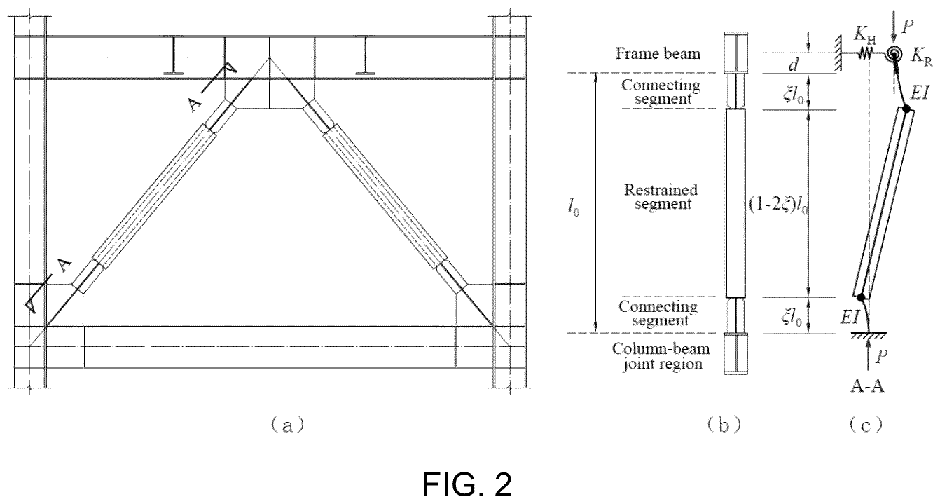

### DETAILED DESCRIPTION OF EMBODIMENTS

In order to make the objects, technical solutions and advantages of the embodiments of the present invention clearer, the technical solutions in the embodiments of the present invention will be clearly and completely described below in conjunction with the accompanying drawings in the embodiments of the present invention. Apparently, the described embodiments are a part of the embodiments of the present invention, rather than all the embodiments. All other embodiments derived by a person of ordinary skill in the art from the embodiments of the present invention without any creative effort fall within the scope of protection of the present invention.

A buckling-restrained brace of the present application is used in a buckling-restrained brace damping system, the buckling-restrained brace damping system includes two buckling-restrained brace subsystems, each of the two buckling-restrained brace subsystems includes a buckling-restrained brace and a gusset plate, and both ends of the buckling-restrained brace are connected to a beam end and a column end via the gusset plate, respectively. Besides, two gusset plates at the above are disposed close to each other, and two buckling-restrained braces are arranged in a herringbone form.

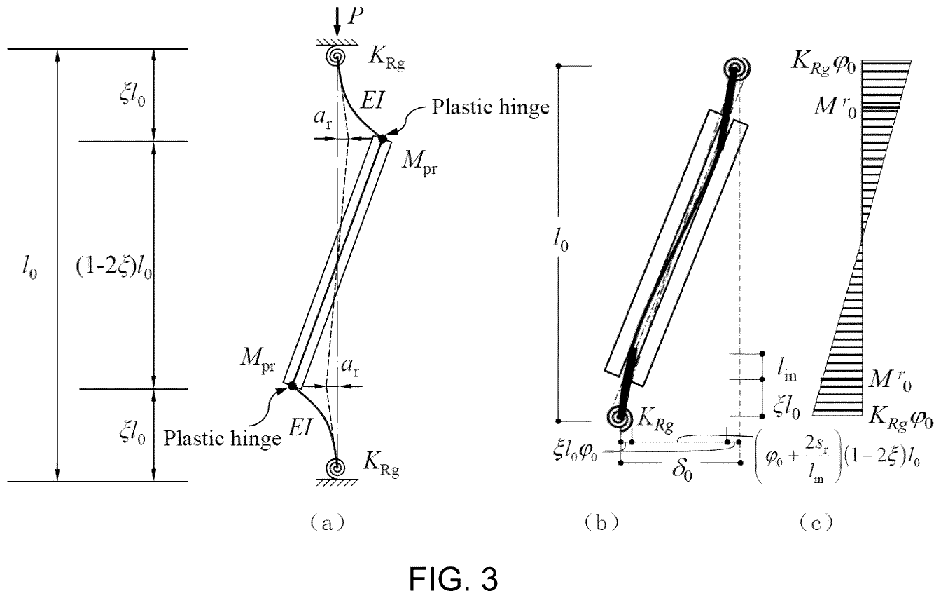

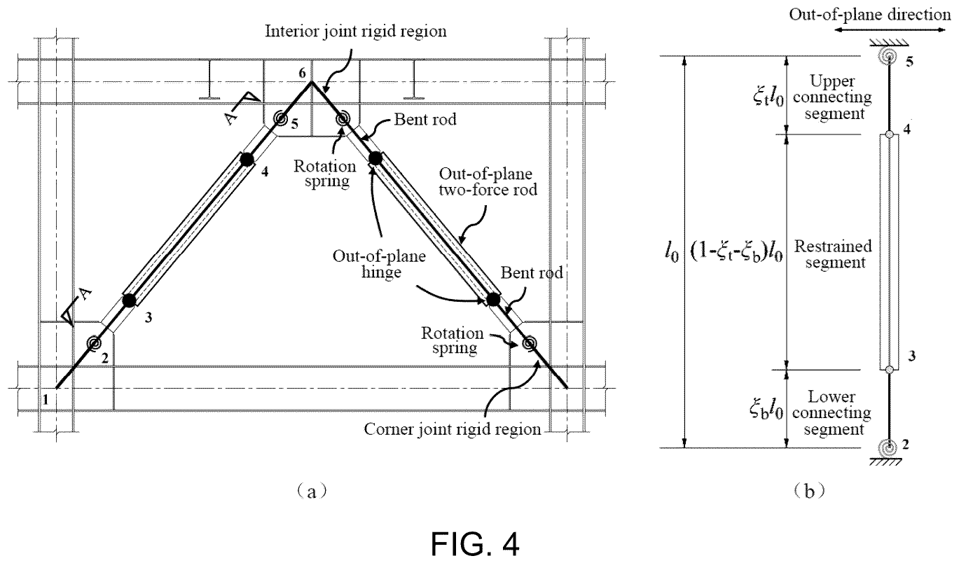

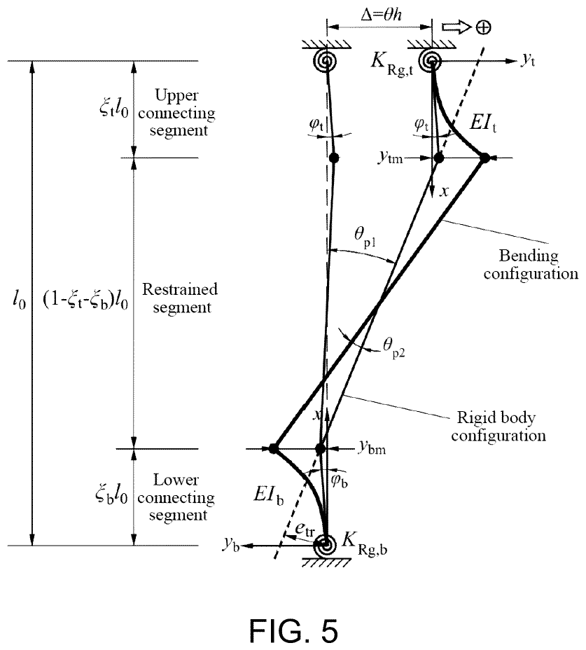

FIG. 4 shows a buckling-restrained brace stability theory analysis model considering a bidirectional seismic action according to the present invention, and an analysis model considering bidirectional stress deformation is shown in FIG. 5. herringbone buckling-restrained brace subframe may be divided into five segments along a supporting axis: a corner joint rigid region (a segment 1-2), a lower connecting segment (a segment 2-3), a buckling-restrained segment (a segment 3-4), an upper connecting segment (a segment 4-5), and an interior joint rigid region (a segment 5-6). According to the experimental phenomena of the inventors, see FIG. 4, it is found that a plastic hinge may appear at length tail endpoints (2 and 5) where the buckling-restrained brace is inserted into the gusset plate under bidirectional stress, and since a certain rotation is allowed, the plastic hinge is simplified here to a rotation spring with certain rotational stiffness. In the design, in order to avoid the adverse effect that eccentric stress generates an extra internal force on the structure, an extension line of the buckling-restrained brace may intersect with a central axis of a beam column at a point, that is, the point 1 in the figure. A corner gusset plate region between the point 2 and a point 1 is considered as a rigid region due to strong constraints of the beam column. A schematic structural diagram of the buckling-restrained brace is as shown in FIG. 1. Intersections of a restrained portion (restrained segment) and unrestrained portions at both ends of a restraining unit generally form a plastic hinge during bidirectional stress, which, however, is considered as out-of-plane hinges (points 3 and 4) here due to the weak out-of-plane restraints. A point 6 is an intersection of the extension line of the buckling-restrained brace and a central axis of an upper beam. The gusset plate has the capacity of out-of-plane rotation, so the out-of-plane rotational stiffness of the gusset plate is considered in the case that out-of-plane rotation springs are used to connect the corner joint rigid region with the lower connecting segment and to connect the interior joint rigid region with the upper connecting segment. Since a core unit reinforced segment of the commonly used buckling-restrained brace is inserted into a restraining member with a short length, it may be assumed that generally, the two may not have two-point contact to produce a bending moment transfer effect, and thus the upper connecting segment or the lower connecting segment and the buckling restrained segment of the brace are considered as articulated in an out-of-plane direction.

The analytical ideas and simplification ideas of the present invention are as follows:

(1) Since the out-of-plane stability is determined by two parts, the first part being an out-of-plane elastic buckling critical force of the buckling-restrained brace, and the second part being out-of-plane ultimate bending moment of the gusset plate, the solution is to calculate the two limit values as a critical value of instability determination. In order to calculate the critical value, the following steps are performed for analysis.

(2) Based on an existing plastic hinge model theory and experimental observation phenomena, a theory analysis model which may consider the rotational stiffness of the gusset plate and the bidirectional seismic action is provided. Referring to FIG. 5, mechanical parameters in the theory analysis model considering the bidirectional seismic action are defined as follows: EI_{b} denotes elastic flexural stiffness of the lower connecting segment, EIₜ denotes elastic flexural stiffness of the upper connecting segment, K_{Rg,b} denotes stiffness of a rotation spring (a corner gusset plate rotation spring) at an end of the lower connecting segment, and N_{Rg,t} denotes stiffness of a rotation spring (a middle gusset plate rotation spring) at an end of the upper connecting segment. The buckling-restrained brace subsystem is subjected to out-of-plane displacement with the magnitude of □=θh. The deformation generated by the buckling-restrained brace consists of two parts. One part is rigid body deformation. In this part, the upper connecting segment and the lower connecting segment make rigid body rotation around the middle gusset plate rotation spring and the corner gusset plate rotation spring by φₜ,φ_{b} respectively, and a yield segment makes rigid body rotation around the out-of-plane hinge joints 3 and 4 shown in FIG. 4, changing from a defect-free geometric configuration to a rigid body configuration. The other part is bending deformation. This part is determined by the flexural stiffness of the upper connecting segment and the lower connecting segment, and combined with a small displacement hypothesis, the hinge joints 3 and 4 produce displacement by y_{bm},yₜₘ respectively as shown in the figure, changing from the rigid body configuration in the figure to a bending configuration position, where the restraining segment has very high flexural stiffness and may be considered as having no bending deformation. θₚ₁,θₚ₂ denotes an acute angle between the rigid body configuration and the non-defect geometric configuration and an acute angle between the rigid body configuration and the bent configuration.

(3) The out-of-plane deformation and stress conditions (mainly indicating the axial force-bending moment interaction) of each component of the buckling-restrained brace subsystem are derived based on the proposed theory analysis model considering the bidirectional seismic action.

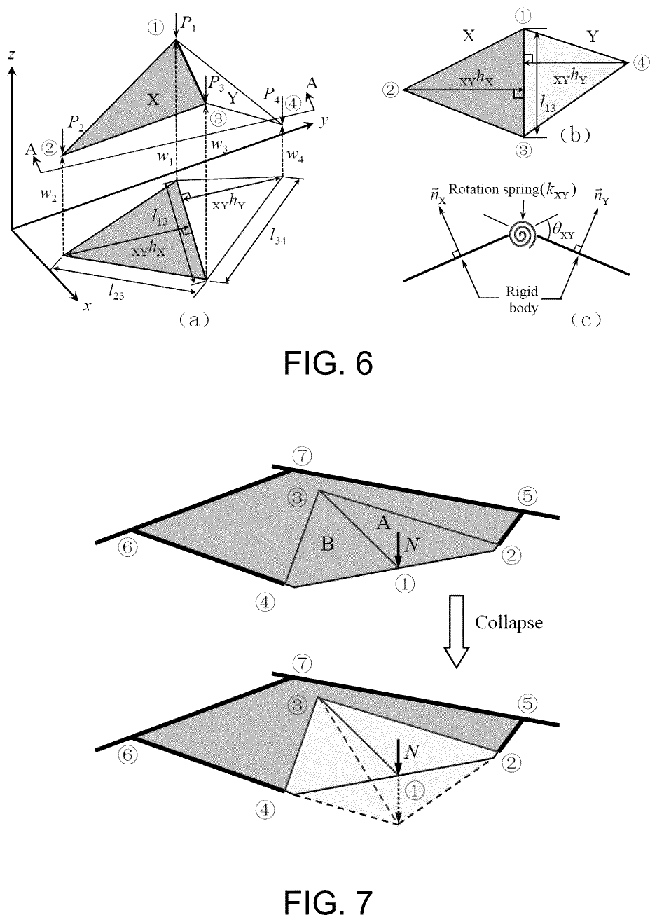

(4) The shear deformation of the gusset plate is ignored, and based on the rigid body spring model (shown in FIG. 6), adjacent triangle element parts that locally make rigid body rotation around any yield line of one of the gusset plates are selected. After this part is subjected to four forces P₁, P₂, P₃, P₄ at four joints (\textcircled{1}, \textcircled{2}, \textcircled{3}, and \textcircled{4}) (the four joints are four vertexes of the two adjacent triangle elements), the yield line \textcircled{1}\textcircled{3} (that is, a connecting line between the joint \textcircled{1} and the joint \textcircled{3}) appears as shown in the figure. The yield line divides the gusset plate into two triangle rigid bodies X and Y. The rigid body spring model regards the yield line as a rotation spring with certain rotational stiffness. _{XY}h_{X} and _{XY}h_{Y} respectively denote distances from the vertexes to the yield line in a vertical XY plane projection (that is, a shape before the out-of-plane displacement) of the two deformed triangle rigid bodies. According to the relationship between the out-of-plane displacement (w₁, w₂, w₃, and w₄) of the joints X and Y and a relative angle (θ_{XY}), the out-of-plane translational stiffness (Pᵢ/wᵢ) of each joint in the figure may be approximated by the principle of virtual work. The expressions of out-of-plane translational stiffness _{XY}K₁₁ and _{XY}K₂₂ of the joint \textcircled{1} and the joint \textcircled{2} in FIG. 6 are as follows:

$${}_{XY} {K}_{11} = \frac{{P}_{1}}{{w}_{1}} = {k}_{XY} \cdot {( \frac{\sqrt{{l}_{23}^{2} - {}_{XY} {h}_{X}^{2}}}{{l}_{13} \cdot {}_{XY} {h}_{X}} + \frac{\sqrt{{l}_{34}^{2} - {}_{XY} {h}_{Y}^{2}}}{{l}_{13} \cdot {}_{XY} {h}_{Y}} )}^{2}$$

$${}_{XY} {K}_{22} = \frac{{P}_{2}}{{w}_{2}} = \frac{{k}_{XY}}{{}_{XY} {h}_{X}^{2}}$$

The rotation spring stiffness k_{XY} is obtained by the following formula:

$${k}_{XY} = D \cdot \frac{2 {l}_{13}}{{}_{XY} {h}_{X} + {}_{XY} {h}_{Y}}$$

Similarly, the expressions of the out-of-plane translational stiffness _{XY}K₃₃ and _{XY}K₄₄ of the joint \textcircled{3} and the joint \textcircled{4} are as follows:

$${}_{XY} {K}_{33} = \frac{{P}_{3}}{{w}_{3}} = {k}_{XY} \cdot {( \frac{\sqrt{{l}_{12}^{2} - {}_{XY} {h}_{X}^{2}}}{{l}_{13} \cdot {}_{XY} {h}_{X}} + \frac{\sqrt{{l}_{14}^{2} - {}_{XY} {h}_{Y}^{2}}}{{l}_{13} \cdot {}_{XY} {h}_{Y}} )}^{2}$$

$${}_{XY} {k}_{44} = \frac{{P}_{4}}{{w}_{4}} = \frac{{k}_{XY}}{{}_{XY} {h}_{Y}^{2}}$$

where lᵢⱼ denotes a distance between a joint i and a joint j, as shown in FIG. 6, and D denotes flexural stiffness of a plate per unit width, calculated by the following formula:

$$D = \frac{{Et}_{g}^{3}}{12 ( 1 - {v}^{2} )}$$

where E and ν denote an elastic modulus and Poisson's ratio of a gusset plate material respectively, and t_{g} denotes a thickness of the gusset plate.

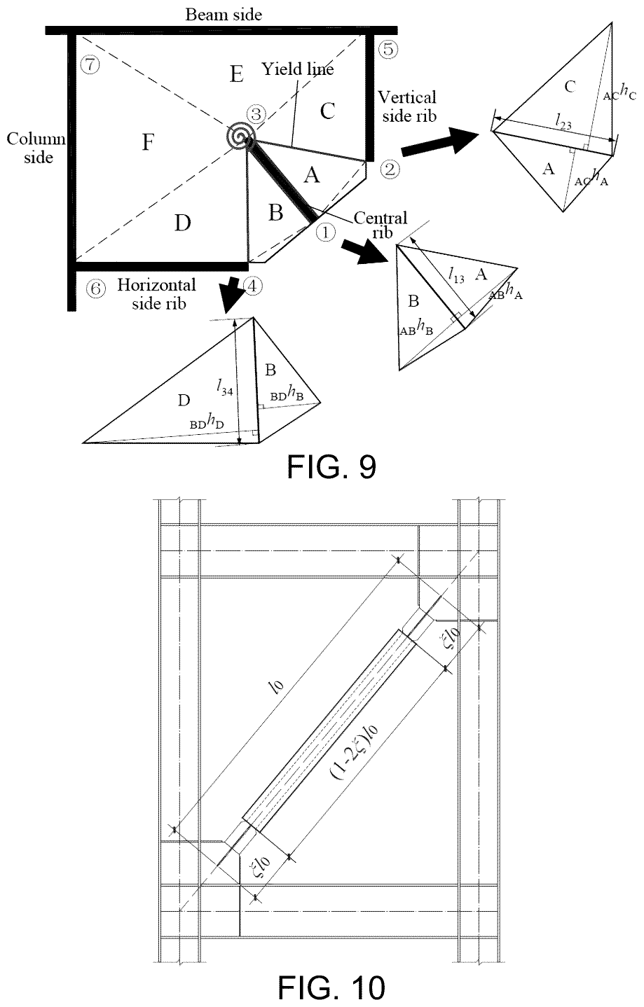

The gusset plate is divided into a plurality of triangle elements according to possible yield lines that may appear in the gusset plate. Specifically, as shown in FIG. 9, the gusset plate is divided into a plurality of triangle elements by connecting lines between the rotation spring (the point 3) generated at a tail end of the part where the buckling-restrained brace is inserted into the gusset plate and the tail endpoints (the points 2 and 4) of a side rib of the gusset plate, an intersection (the point 5) of the side rib and a beam, an intersection (the point 6) of the side rib and a column, a beam-column intersection (the point 7), a connection edge (the point 1) between the buckling-restrained brace and the gusset plate, and a connecting line between the points 2 and 4. A connecting edge of two adjacent triangle elements is a yield line that may appear in the gusset plate, and each triangle element is regarded as a rigid body. In FIG. 7, by setting rotation spring connection at a boundary (that is, a position where the yield line appears in the rigid body spring model) and rigid boundary conditions (rigid constraints of the side rib and the beam column side), when the gusset plate meets the rigid boundary conditions, the out-of-plane translational displacement of the joints \textcircled{2}-\textcircled{7} in FIG. 7 is almost 0, so that an out-of-plane concentrated force N may act on the joint \textcircled{1} in FIG. 7. Through embodiment verification, the rotational stiffness of the point \textcircled{3} of the gusset plate in FIG. 9 is approximated as being only related to triangle elements A, B, C and D (that is, the connecting line between the joints \textcircled{1} and \textcircled{2}, the connecting line between the joints \textcircled{1} and \textcircled{3}, and the connecting line between the joints \textcircled{2} and \textcircled{3}; the connecting line between the joints \textcircled{1} and \textcircled{4}, the connecting line between the joints \textcircled{1} and \textcircled{3}, and the connecting line between the joints \textcircled{3} and \textcircled{4}; the connecting line between the joints \textcircled{2} and \textcircled{5}, the connecting line between the joints \textcircled{3} and \textcircled{5}, and the connecting line between the joints \textcircled{2} and \textcircled{3}; and the connecting line between the joints \textcircled{3} and \textcircled{4}, the connecting line between the joints \textcircled{3} and \textcircled{6}, and the connecting line between the joints \textcircled{4} and \textcircled{6} respectively), so that the out-of-plane rotational stiffness of the gusset plate is considered.

(5) For safety reasons, the out-of-plane flexural stiffness of an overhang segment of the buckling-restrained brace is taken as the flexural stiffness of the connecting segment. Based on a yield design principle of an edge fiber, stability design criteria of the gusset plate e based on yield line analysis are proposed. The design criteria involve the calculation of the rotational stiffness K_{Rg} and the ultimate bending moment M_{gu} of the gusset plate, and serve as a final judgment criterion for the bidirectional stress stability of the buckling-restrained brace.

(6) A theoretical design formula obtained from the previous step is simplified with mathematical methods and a symmetric analysis model, so as to facilitate engineering application.

The symmetric analysis model means that for the calculation model given in (b) of FIG. 4, the upper connecting segment and the lower connecting segment are equal in length (ξₜ=ξ_{b}, where ξ denotes a ratio of the lengths l₄₋₅ and l₂₋₃ of the upper connecting segment and the lower connecting segment (the segment 4-5 and the segment 2-3) to the length l₀ of the buckling-restrained brace, and subscripts t and b denote the upper connecting segment and the lower connecting segment respectively); the upper connecting segment and the lower connecting segment have equal out-of-plane flexural stiffness (EI_{b}=EIₜ, where EI denotes the out-of-plane flexural stiffness of the upper connecting segment and the lower connecting segment of the buckling-restrained brace); and gusset plates connected up and down are equal in out-of-plane rotational stiffness, (K_{Rg,t}=K_{Rg,b}, where K_{Rg} denotes the out-of-plane rotational stiffness of the upper gusset plate and the lower gusset plate, that is, the stiffness provided by the rotation springs of the points 3 and 6 in the figure), which may actually well match the general engineering due to the symmetrical design (material, design, etc.) between the upper connecting segment and the lower connecting segment as well as between the upper gusset plate and the lower gusset plate.

Upon simplification, a buckling-restrained brace out-of-plane stability design method considering a bidirectional seismic action according to the present invention includes the following steps:

Step 1: A dimension of a gusset plate, a geometric dimension of a buckling-restrained brace, and a target out-of-plane displacement angle are determined.

The dimension of the gusset plate is determined according to the maximum axial pressure of the buckling-restrained brace. In some embodiments of the present invention, the dimension of the gusset plate is preliminarily determined by 1.5 times of the yield force of the buckling-restrained brace. This is because the buckling-restrained brace requires energy dissipation in the plastic stage during operation, and stress is often greater than the yield axial force. The main reason of amplifying the yield axial force before the design is to have a certain degree of safety redundancy. In other embodiments, the dimension of the gusset plate may be preliminarily determined by other multiples of the yield force of the buckling-restrained brace.

The section dimensions and geometric lengths of a yield segment and the strengthened segment of the buckling-restrained brace are determined by an axial compression design method according to the “Technical specification for buckling restrained braces” or the current local regulations, and the parameters in the calculation model of the hypothesis (6) of the buckling-restrained brace subsystem are determined according to the design dimensions (that is, the length, section, etc., of each segment in FIG. 1) of the buckling-restrained brace.

In some embodiments of the present invention, the requirements for the required yield force and axial elastic stiffness need to be determined according to actual design conditions, an allowable inter-story drift index, etc.

The target out-of-plane displacement angle is selected during design. In some embodiments of the present invention, a target out-of-plane displacement angle θ=2% of the frame structure under rare earthquakes may be used. In other embodiments, the target out-of-plane displacement angle may be other values.

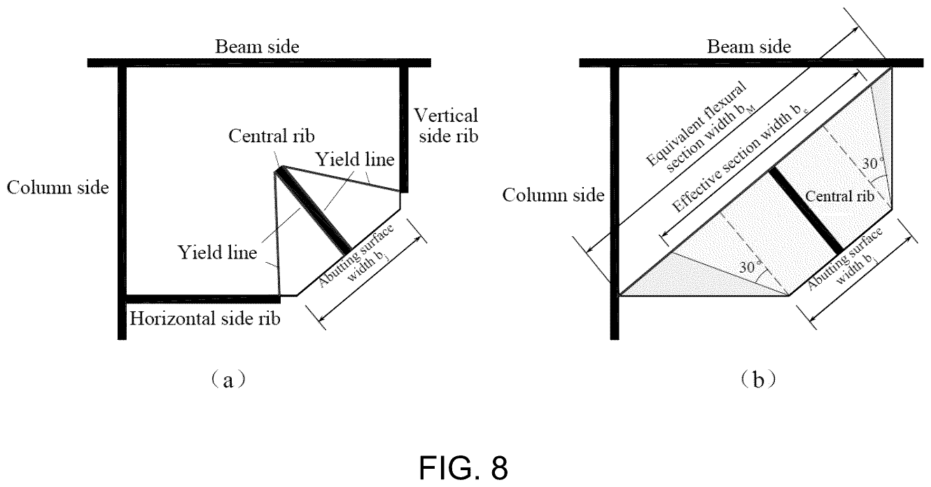

Step 2: Referring to FIG. 8, a connecting line between an intersection joint of a horizontal side rib and a column side and an intersection joint of a vertical side rib and a beam side is an equivalent flexural section width b_{M}, an effective section width bₑ is obtained by inward extending two endpoints of an abutting surface width b_{J} of an unrestrained side of the gusset plate to a straight line where b_{M} is located at an angle 30° deviated from a central rib, and the yield axial force of the 30° angle effective section of the gusset plate is calculated based on the equivalent width. A calculation formula of the yield axial force P_{gy} of the gusset plate is:

$${P}_{gy} = {b}_{e} {t}_{g} {f}_{gy} \qquad ( 1 )$$

where
P_{gy}—Yield axial force of the 30° angle effective section of the gusset plate
bₑ—Width (mm) of the effective section formed by the gusset plate according to a 30° diffusion line
t_{g}—Thickness (mm) of the gusset plate
f_{gy}—Yield strength (N/mm²) of the gusset plate

Step 3: For the gusset plate shown in FIG. 9, the rotational stiffness K_{Rg} and ultimate bending moment M_{gu} of the gusset plate are calculated by formulas (2) to (9), and the inertia moment I in an out-of-plane direction is calculated according to a section of an overhang segment of the buckling-restrained brace, and then multiplied by the elastic modulus E of the gusset plate material to calculate out-of-plane flexural stiffness EI of the overhang segment of the buckling-restrained brace as the flexural stiffness of the connecting segment.

$${k}_{AB} = \frac{{Et}_{g}^{3}}{12 ( 1 - {v}^{2} )} \cdot \frac{2 {l}_{13}}{{}_{AB} {h}_{A} + {}_{AB} {h}_{B}} \qquad ( 2 )$$

$${k}_{A C} = \frac{{Et}_{g}^{3}}{12 ( 1 - {v}^{2} )} \cdot \frac{2 {l}_{23}}{{}_{A C} {h}_{A} + {}_{A C} {h}_{C}} \qquad ( 3 )$$

$${k}_{BD} = \frac{{Et}_{g}^{3}}{12 ( 1 - {v}^{2} )} \cdot \frac{2 {l}_{34}}{{}_{BD} {h}_{B} + {}_{BD} {h}_{D}} \qquad ( 4 )$$

$${}_{A C} {K}_{11} = \frac{{k}_{A C}}{{}_{A C} {h}_{A}^{2}} \qquad ( 5 )$$

$${}_{BD} {K}_{11} = \frac{{k}_{BD}}{{}_{BD} {h}_{B}^{2}} \qquad ( 6 )$$

$${}_{AB} {K}_{11} = {k}_{AB} \cdot {( \frac{\sqrt{{l}_{23}^{2} - {}_{AB} {h}_{A}^{2}}}{{l}_{13} \cdot {}_{AB} {h}_{A}} + \frac{\sqrt{{l}_{34}^{2} - {}_{AB} {h}_{B}^{2}}}{{l}_{13} \cdot {}_{AB} {h}_{B}} )}^{2} \qquad ( 7 )$$

$${K}_{Rg} = {(}_{AB} {K}_{11} + {}_{A C} {K}_{11} + {}_{BD} {K}_{11} ) {l}_{13}^{2} \qquad ( 8 )$$

$${M}_{gu} = \frac{{f}_{gy} {t}_{g}^{2}}{4} \cdot {l}_{13} \cdot ( \frac{\sqrt{{l}_{23}^{2} - {}_{AB} {h}_{A}^{2}}}{{}_{AB} {h}_{A}} + \frac{\sqrt{{l}_{34}^{2} - {}_{AB} {h}_{B}^{2}}}{{}_{AB} {h}_{B}} + \frac{{l}_{23}}{{}_{A C} {h}_{A}} + \frac{{l}_{34}}{{}_{BD} {h}_{B}} ) \qquad ( 9 )$$

where
ν—Poisson's ratio of the gusset plate
E—Elastic modulus of the gusset plate
l₁₃, l₃₄ and l₂₃—Distance between the joints \textcircled{1} and \textcircled{3}, a distance between the joints \textcircled{3} and \textcircled{4}, and a distance between the joints \textcircled{2} and \textcircled{3}
_{AC}h_{A} and _{AC}h_{C}—Distance from vertexes of the triangle elements A and C to an AC yield line \textcircled{2}\textcircled{3} in an original figure
_{AB}h_{A} and _{AB}h_{B}—Distance from vertexes of the triangle elements A and B to an AB yield line \textcircled{1}\textcircled{3} in the original figure
_{BD}h_{B} and _{BD}h_{D}—Distance from vertexes of the triangle elements B and D to a BD yield line \textcircled{3}\textcircled{4} in the original figure
k_{AB}, k_{AC} and k_{BD}—Rotation spring stiffnesses between the triangle elements A and B, the triangle elements A and C, and the triangle elements B and D
_{AB}K₁₁, _{AC}K₁₁ and _{BD}K₁₁—Out-of-plane translational stiffnesses of the joint \textcircled{1} provided by the triangle elements A and B, the triangle elements A and C, and the triangle elements B and D
K_{Rg}—Out-of-plane rotational stiffness of the gusset plate
M_{gu}—Out-of-plane ultimate bending moment of the gusset plate

Step 4: For the buckling-restrained brace subframe in FIG. 10, the out-of-plane elastic buckling critical force of the buckling-restrained brace is calculated by formula (10).

$${P}_{cr} = \frac{( 1 - 2 ξ ) {π}^{2} E I}{{( 2 ξ {l}_{0} )}^{2}} \cdot \frac{{K}_{Rg} ξ {l}_{0} / E I}{{K}_{Rg} ξ {l}_{0} / E I + {π}^{2} / 4} \qquad ( 10 )$$

where
P_{cr}—Out-of-plane elastic buckling critical force (N) of the buckling-restrained brace
l₀—Length (mm) of a supporting axis calculated from a center stiffener of the gusset plate (FIG. 10)
ξ—Ratio of a length between one end of a restraining unit and a root of a center rib of the nearest gusset plate along the supporting axis to l₀ (FIG. 10)
I—Out-of-plane inertia moment (a section B-B in FIG. 1) of the overhang connecting segment of the buckling-restrained brace

Step 5: A trigger eccentricity (shown in FIG. 5) is calculated by formula (11); whether out-of-plane stability of the brace is met is checked by formula (12); if the out-of-plane stability of the brace is met, it is determined that the buckling-restrained brace damping system designed including the buckling-restrained brace subsystems which is constructed based on the parameters obtained by the above-mentioned steps is capable of ensuring the out-of-plane stability under the bidirectional seismic action; and if the out-of-plane stability of the brace is not met, it is determined that a buckling-restrained brace damping system is to suffer out-of-plane instability under the bidirectional seismic action, and step 1 needs to be performed to re-determine the geometric dimensions of the buckling-restrained brace and each of the two gusset plates and the target out-of-plane displacement angle θ, so as to at last construct the buckling-restrained brace damping system which is capable of ensuring the out-of-plane stability of the buckling-restrained brace under the bidirectional seismic action.

$${e}_{tr} = \frac{ξ θ h}{1 - 2 ξ} \qquad ( 11 )$$

$${P}_{li m} = \frac{{P}_{gy}}{2} + \frac{{P}_{cr}}{2} + \frac{{P}_{gy} {P}_{cr} {e}_{tr}}{2 {M}_{gu}} - \sqrt{{( \frac{{P}_{gy}}{2} + \frac{{P}_{cr}}{2} + \frac{{P}_{gy} {P}_{cr} {e}_{tr}}{2 {M}_{gu}} )}^{2} - {P}_{gy} {P}_{cr}} > {N}_{u} \qquad ( 12 )$$

where eₜᵣ denotes the trigger eccentricity, h denotes a storey height (m) of the subframe, θ denotes a designed inter-story drift angle, Pₗᵢₘ denotes an out-of-plane ultimate load (N) of the buckling-restrained brace, Nᵤ denotes the maximum axial pressure of the buckling-restrained brace, which may be calculated by 1.5 times of the yield axial force of the brace (N), M_{gu} denotes the ultimate bending moment of the gusset plate, P_{gy} denotes the yield axial force of the 30° angle effective section of the gusset plate, and P_{cr} denotes the out-of-plane elastic buckling critical force (N) of the buckling-restrained brace.

Other parameters are calculated and defined by formulas (1) to (11).

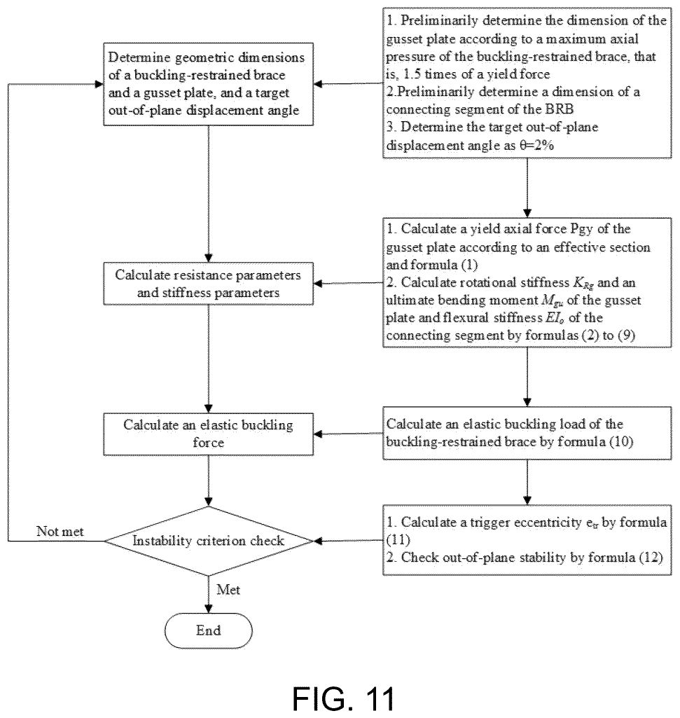

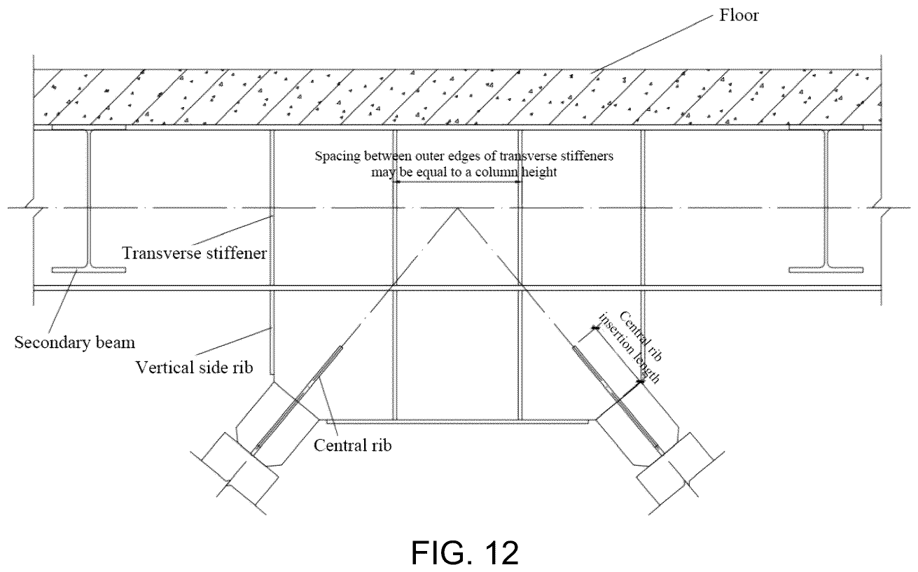

FIG. 11 shows a design flow of the present invention.

The application of the herringbone buckling-restrained brace out-of-plane stability practical design method according to the embodiments of the present invention should meet the following two preconditions: first, the buckling-restrained brace subsystem meets the symmetric analysis model; and second, a main beam of the frame does not undergo torsional deformation under the seismic action, so as to avoid calculating the rotation spring stiffness of the main beam. Therefore, the structure requirements of the buckling-restrained brace out-of-plane stability design method according to the present invention are as follows:

(1) It is ensured that gusset plates connected to two ends of the buckling-restrained brace have consistent central rib insertion length.

(2) The middle gusset plate should be constructed with double transverse stiffeners, and the distance of the transverse stiffeners should meet the structure requirements as shown in FIG. 12. That is, the transverse stiffeners should be arranged in the middle of the main beam of the frame, the distance between outer edges of the transverse stiffeners may be equal to the height of a column section, the positions of the stiffeners should correspond to vertical side ribs and transverse ribs of the middle gusset plate, the main beam of the frame should be provided with a secondary beam and paved with a floor, and the secondary beam should be as close as possible to the middle of the main beam of the frame.

Although the middle joint structure of the present invention is proposed for the herringbone buckling-restrained brace steel frame, the frame beam adopts an open thin-wall I-beam, mainly because the I-beam has weak torsional stiffness and is prone to torsion. In the case that a box beam is adopted as the frame beam or the buckling-restrained brace is located in a reinforced concrete frame, the torsional stiffness of the beams is much higher than that of the open thin-wall I-beam, and the section of the beams is not prone to distortion, so the application conditions of the practical design method may be better met.

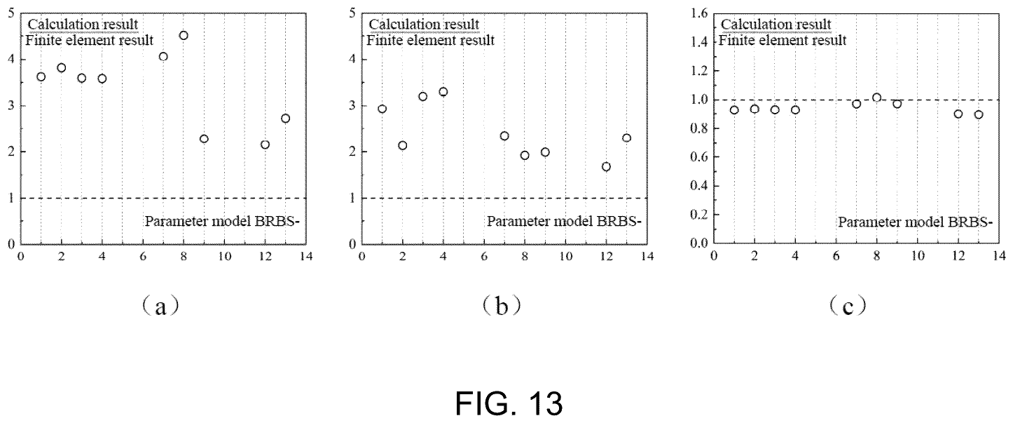

FIG. 13 shows the comparison of the existing separated design method, the existing integral design method, and the practical design method considering the bidirectional seismic action according to the present invention with a finite element modeling result. Parameters of a finite element model are shown in Table 1, which correspond to the key parameters of calculation in the design steps and correspond to the parameters in FIG. 5 and FIG. 10, and are subjected to bidirectional synchronous loading to simulate the bidirectional seismic action. In FIG. 13, the horizontal axis indicates the number of 9 models, and the vertical axis indicates a ratio of an out-of-plane buckling axial force of the buckling-restrained brace calculated according to a corresponding design method to a finite element calculation result. It may be seen that calculation results of the existing separated design method and the existing integral design method significantly overestimate the out-of-plane stability bearing capacity of the buckling-restrained brace, while a calculation result obtained by the practical design method according to the present invention is very close to the finite element calculation result, indicating that the method according to the present invention may accurately consider the influence of the bidirectional seismic action on the out-of-plane stability of the buckling-restrained brace and provide a correct theoretical estimation.

TABLE 1
Key parameters of the analysis model

| | l₀ | | EI | P_{gy} | M_{gu} | K_{Rg} | θ | h |
|---|---|---|---|---|---|---|---|---|
| Model | (m) | ξ | (kN · m²) | (kN) | (kN · m) | (kN · m/rad) | (%) | (m) |
| BRBS-1 | 2.9215 | 0.130 | 706 | 1308.9 | 13.5 | 779.6 | 2.87 | 3 |
| BRBS-2 | 2.9215 | 0.130 | 174 | 1308.9 | 13.5 | 779.6 | 2.5 | 3 |
| BRBS-3 | 2.9215 | 0.130 | 1830 | 1308.9 | 13.5 | 779.6 | 2.93 | 3 |
| BRBS-4 | 2.9215 | 0.130 | 3771 | 1308.9 | 13.5 | 779.6 | 2.96 | 3 |
| BRBS-7 | 2.9215 | 0.161 | 706 | 1308.9 | 13.5 | 779.6 | 2 | 3 |
| BRBS-8 | 2.9215 | 0.192 | 706 | 1308.9 | 13.5 | 779.6 | 1.33 | 3 |
| BRBS-9 | 2.9215 | 0.130 | 706 | 1047.1 | 8.6 | 399.2 | 1.55 | 3 |
| BRBS-12 | 2.8015 | 0.114 | 706 | 1069.9 | 6.9 | 260.9 | 1.5 | 3 |
| BRBS-13 | 2.8615 | 0.122 | 706 | 1189.4 | 9.8 | 470.1 | 2.3 | 3 |

Note:
The out-of-plane inter-story drift of the model is Δ = θ h.

The above description of the disclosed embodiments is provided to enable any person skilled in the art to implement or use the present invention. Various modifications to these embodiments will be readily apparent to persons skilled in the art, and the generic principles defined herein may be implemented in other embodiments without departing from the spirit or scope of the present invention. Thus, the present invention is not intended to be limited to the embodiments shown herein but is to be accorded the widest scope consistent with the principles and novel features disclosed herein.

What is claimed is:

1. A buckling-restrained brace out-of-plane stability design method considering a bidirectional seismic action, wherein a buckling-restrained brace is used in a buckling-restrained brace damping system, the buckling-restrained brace damping system comprises a buckling-restrained brace subsystem, the buckling-restrained brace subsystem comprises the buckling-restrained brace and a gusset plate, both ends of the buckling-restrained brace are connected to a beam end and a column end via the gusset plate, respectively, and the method comprises the following steps:
step 1: providing a designed buckling-restrained brace subsystem including a frame, a buckling-restrained brace and two gusset plates, the frame comprising beams and columns, the two gusset plates fixed to the beams, and two sides of the buckling-restrained brace inserted into the two gusset plates, determining geometric dimensions of the buckling-restrained brace and each of the two gusset plates, and a target out-of-plane displacement angle θ;
step 2: calculating resistance parameters and stiffness parameters, the resistance parameters comprising a yield axial force P_{gy} of the each of the two gusset plates, and the stiffness parameters comprising a rotational stiffness K_{Rg} of the each of the two gusset plates, an ultimate bending moment M_{gu} of the each of the two gusset plates, and flexural stiffnesses of connecting segments of the buckling-restrained brace; wherein each of the two gusset plates comprises a horizontal side rib and a vertical side rib, and for the yield axial force of the each of the two gusset plates, the yield axial force of the each of the two gusset plates being calculated according to a 30° angle effective section of the each of the two gusset plates, wherein a connecting line between an intersection joint of the horizontal side rib and a column side and an intersection joint of the vertical side rib and a beam side is an equivalent flexural section width b_{M}, an effective section width bₑ is obtained by inward extending two endpoints of an abutting surface width b_{J} of an unrestrained side of the each of the two gusset plates to a straight line where equivalent flexural section width b_{M} is located at an angle 30° deviated from a central rib, and the yield axial force P_{gy} of the each of the two gusset plates is calculated based on the effective section width bₑ; a shear deformation of the each of the two gusset plates being ignored, and the rotational stiffness K_{Rg} of the each of the two gusset plates and the ultimate bending moment M_{gu} of the each of the two gusset plates being obtained based on a rigid body spring model;
step 3: calculating an out-of-plane elastic buckling critical force P_{cr} of the buckling-restrained brace; and
step 4: calculating a trigger eccentricity eₜᵣ, checking whether an out-of-plane stability of the buckling-restrained brace is met based on the trigger eccentricity eₜᵣ, the out-of-plane elastic buckling critical force P_{cr} of the buckling-restrained brace, the ultimate bending moment M_{gu} of the each of the two gusset plates, and a maximum axial pressure Nᵤ of the buckling-restrained brace, an expression for checking the out-of-plane stability of the buckling-restrained brace is:
$${P}_{li m} = \frac{{P}_{gy}}{2} + \frac{{P}_{cr}}{2} + \frac{{P}_{gy} {P}_{cr} {e}_{tr}}{2 {M}_{gu}} - \sqrt{{( \frac{{P}_{gy}}{2} + \frac{{P}_{cr}}{2} + \frac{{P}_{gy} {P}_{cr} {e}_{tr}}{2 {M}_{gu}} )}^{2} - {P}_{gy} {P}_{cr}} > {N}_{u}$$
wherein Pₗᵢₘ denotes an out-of-plane ultimate load of the buckling-restrained brace, P_{gy} denotes the yield axial force of the 30° angle effective section of the each of the two gusset plates, and the maximum axial pressure Nᵤ of the buckling-restrained brace, the ultimate bending moment M_{gu} of the each of the two gusset plates, the yield axial force P_{gy} of the 30° angle effective section of the each of the two gusset plates, the out-of-plane elastic buckling critical force P_{cr} of the buckling-restrained brace, and the trigger eccentricity eₜᵣ related to the geometric dimensions of the buckling-restrained brace and the each of the two gusset plates;
if the out-of-plane stability of the buckling-restrained brace is met, determining that the buckling-restrained brace damping system comprising the buckling-restrained brace subsystem which is constructed based on the parameters obtained by the above-mentioned steps is capable of ensuring the out-of-plane stability of the buckling-restrained brace under the bidirectional seismic action, and constructing a building structure by providing the designed buckling-restrained brace subsystem including the frame, the buckling-restrained brace and the two gusset plates, the frame comprising the beams and the columns, the two gusset plates fixed to the beams, and the two sides of the buckling-restrained brace inserted into the two gusset plates based on the designed buckling-restrained brace subsystem in the step 1; and if the out-of-plane stability of the buckling-restrained brace is not met, determining that the designed buckling-restrained brace damping system is to suffer out-of-plane instability under the bidirectional seismic action, and returning to step 1 to re-determine the geometric dimensions of the buckling-restrained brace and each of the two gusset plates and the target out-of-plane displacement angle θ, so as to at last construct the buckling-restrained brace damping system which is capable of ensuring the out-of-plane stability of the buckling-restrained brace under the bidirectional seismic action.

2. The buckling-restrained brace out-of-plane stability design method considering a bidirectional seismic action according to claim 1, wherein in step 2, a calculation formula of the yield axial force of the each of the two gusset plates is:
$${P}_{gy} = {b}_{e} {t}_{g} {f}_{gy}$$
wherein P_{gy} denotes the yield axial force of the 30° angle effective section of the each of the two gusset plates, bₑ denotes a width of an effective section formed according to a 30° diffusion line of the each of the two gusset plates, t_{g} denotes a thickness of the each of the two gusset plates, and f_{gy} denotes an yield strength of the each of the two gusset plates.

3. The buckling-restrained brace out-of-plane stability design method considering a bidirectional seismic action according to claim 1, wherein in step 2, with the shear deformation of each of the two the gusset plates ignored, the each of the two gusset plates is divided into a plurality of triangle elements according to possible yield lines of the each of the two gusset plates, wherein a rotation spring generated at a tail of a part where the buckling-restrained brace is inserted into the each of the two gusset plates is defined as a third joint, a tail endpoint of the horizontal side rib of the each of the two gusset plates is defined as a fourth joint, a tail endpoint of the vertical side rib of the each of the two gusset plates is defined as a second joint, an intersection of the vertical side rib and the beam side is defined as a fifth joint, an intersection of the horizontal side rib and the column side is defined as a sixth joint, an intersection of the beam side and the column side is defined as a seventh joint, and a connecting edge between the buckling-restrained brace and the each of the two gusset plates is defined as a first joint; connecting lines between the third joint with the first joint, the second joint, the fourth joint, the fifth joint, the sixth joint and the seventh joint divide the each of the two gusset plates into the plurality of triangle elements, and connecting edges between every two adjacent triangular elements of the triangle elements are the possible yield lines of the each of the two gusset plates; each of the triangle elements is regarded as a rigid body, and an out-of-plane concentrated force N acts on the first joint, wherein a connecting line between the first joint and the second joint, a connecting line between the first joint and the third joint, and a connecting line between the second joint and the third joint are defined to form a triangle element A; a connecting line between the first joint and the fourth joint, the connecting line between the first joint and the third joint, and a connecting line between the third joint and the fourth joint are defined to form a triangle element B; a connecting line between the second joint and the fifth joint, a connecting line between the third joint and the fifth joint, and the connecting line between the second joint and the third joint are defined to form a triangle element C; the connecting line between the third joint and the fourth joint, a connecting line between the third joint and the sixth joint, and a connecting line between the fourth joint and the sixth joint—are defined to form a triangle element D; and a rotational stiffness of the third joint of the each of the two gusset plates is considered to be related only to the triangle elements A, B, C and D, thereby obtaining:
$${k}_{A B} = \frac{{Et}_{g}^{3}}{12 ( 1 - {v}^{2} )} \cdot \frac{2 {l}_{13}}{{}_{AB} {h}_{A} + {}_{AB} {h}_{B}} \qquad ( 2 )$$
$${k}_{A C} = \frac{{Et}_{g}^{3}}{12 ( 1 - {v}^{2} )} \cdot \frac{2 {l}_{23}}{{}_{A C} {h}_{A} + {}_{A C} {h}_{C}} \qquad ( 3 )$$
$${k}_{B D} = \frac{{Et}_{g}^{3}}{12 ( 1 - {v}^{2} )} \cdot \frac{2 {l}_{34}}{{}_{BD} {h}_{B} + {}_{BD} {h}_{D}} \qquad ( 4 )$$
$${}_{A C} {K}_{11} = \frac{k}{{}_{A C} {h}_{A}^{2}} \qquad ( 5 )$$
$${}_{BD} {K}_{11} = \frac{{k}_{B D}}{{}_{BD} {h}_{B}^{2}} \qquad ( 6 )$$
$${}_{AB} {K}_{11} = {k}_{A B} \cdot {( \frac{\sqrt{{l}_{23}^{2} - {}_{AB} {h}_{A}^{2}}}{{l}_{13} \cdot {}_{AB} {h}_{A}} + \frac{\sqrt{{l}_{34}^{2} - {}_{AB} {h}_{B}^{2}}}{{l}_{13} \cdot {}_{AB} {h}_{B}} )}^{2} \qquad ( 7 )$$
where k_{AB}, k_{AC} and k_{BD} denote rotation spring stiffnesses between the triangle elements A and B, the triangle elements A and C, and the triangle elements B and D respectively, E denotes an elastic modulus of a gusset plate material, t_{g} denotes the thickness of the each of the two t gusset plates, ν denotes a Poisson's ratio of the each of the two gusset plates, _{AB}h_{A} and _{AB}h_{B} denote distances from vertexes of the triangle elements A and B to an AB yield line respectively, _{AC}h_{A} and _{AC}h_{C} denote distances from vertexes of the triangle elements A and C to an AC yield line respectively, _{BD}h_{B} and _{BD}h_{D} denote distances from vertexes of the triangle elements B and D to a BD yield line respectively, _{AB}K₁₁, _{AC}K₁₁ and _{BD}K₁₁ denote out-of-plane translational stiffnesses of the first joint provided by the triangle elements A and B, the triangle elements A and C, and the triangle elements B and D respectively, and l₁₃, l₃₄ and l₂₃ denote distances between the first joint and the third joint, the third joint and the fourth joint, and the second joint and the third joint respectively.

4. The buckling-restrained brace out-of-plane stability design method considering a bidirectional seismic action according to claim 3, wherein in step 2, a calculation formula of the rotational stiffness K_{Rg} of the each of the two gusset plates is:
$${K}_{Rg} = {(}_{A B} {K}_{11} + {}_{A C} {K}_{11} + {}_{BD} {K}_{11} ) {l}_{13}^{2} .$$

5. The buckling-restrained brace out-of-plane stability design method considering a bidirectional seismic action according to claim 3, wherein a calculation formula of the ultimate bending moment M_{gu} of the each of the two gusset plates is:
$${M}_{gu} = \frac{{f}_{gy} {t}_{g}^{2}}{4} \cdot {l}_{13} \cdot ( \frac{\sqrt{{l}_{23}^{2} - {}_{AB} {h}_{A}^{2}}}{{}_{AB} {h}_{A}} + \frac{\sqrt{{l}_{34}^{2} - {}_{AB} {h}_{B}^{2}}}{{}_{AB} {h}_{B}} + \frac{{l}_{23}}{{}_{A C} {h}_{A}} + \frac{{l}_{34}}{{}_{BD} {h}_{B}} )$$
wherein f_{gy} denotes the yield strength of the each of the two gusset plates.

6. The buckling-restrained brace out-of-plane stability design method considering a bidirectional seismic action according to claim 1, wherein step 2 further comprises a calculation of the flexural stiffnesses of the connecting segments, wherein an inertia moment I in an out-of-plane direction is calculated according to a section of an overhang segment of the buckling-restrained brace, and then multiplied by an elastic modulus E of a gusset plate material to calculate out-of-plane flexural stiffness EI of the overhang segment of the buckling-restrained brace, and the out-of-plane flexural stiffness of the overhang segment of the buckling-restrained brace is used as the flexural stiffnesses of the connecting segments.

7. The buckling-restrained brace out-of-plane stability design method considering a bidirectional seismic action according to claim 1, wherein in step 3, a calculation formula of the out-of-plane elastic buckling critical force of the buckling-restrained brace is:
$${P}_{cr} = \frac{( 1 - 2 ξ ) {π}^{2} E I}{{( 2 ξ {l}_{0} )}^{2}} \cdot \frac{{K}_{Rg} ξ {l}_{0} / E I}{{K}_{Rg} ξ {l}_{0} / E I + {π}^{2} / 4}$$
wherein P_{cr} denotes the out-of-plane elastic buckling critical force of the buckling-restrained brace, l₀ denotes a length of a supporting axis calculated from a center stiffener of the each of the two gusset plates, ξ denotes a ratio of a length between one end of a restraining unit and a root of a center rib of a nearest gusset plate along the supporting axis to l₀, and I denotes an out-of-plane inertia moment of an overhang connecting segment of the buckling-restrained brace.

8. The buckling-restrained brace out-of-plane stability design method considering a bidirectional seismic action according to claim 1, wherein in step 4, a calculation formula of the trigger eccentricity eₜᵣ is:
$${e}_{tr} = \frac{ξ θ h}{1 - 2 ξ}$$
wherein eₜᵣ denotes the trigger eccentricity, h denotes a height of a subframe, θ denotes the target out-of-plane displacement angle, and ξ denotes a ratio of a length between one end of a restraining unit and a root of a center rib of a nearest gusset plate along a supporting axis to l₀.

9. The buckling-restrained brace out-of-plane stability design method considering a bidirectional seismic action according to claim 1, wherein the application of the design method needs to meet the following two conditions: the buckling-restrained brace subsystem meets a symmetric analysis model, and a main beam of a frame does not undergo a torsion deformation under the bidirectional seismic action, wherein in the symmetric analysis model, an upper connecting segment and a lower connecting segment of the buckling-restrained brace are equal in length, the upper connecting segment and the lower connecting segment have equal out-of-plane flexural stiffnesses, and the two gusset plates connected up and down have equal out-of-plane rotational stiffnesses.

10. The buckling-restrained brace out-of-plane stability design method considering a bidirectional seismic action according to claim 2, wherein the application of the design method needs to meet the following two conditions: the buckling-restrained brace subsystem meets a symmetric analysis model, and a main beam of a frame does not undergo a torsion deformation under the bidirectional seismic action, wherein in the symmetric analysis model, an upper connecting segment and a lower connecting segment of the buckling-restrained brace are equal in length, the upper connecting segment and the lower connecting segment have equal out-of-plane flexural stiffnesses, and the two gusset plates connected up and down have equal out-of-plane rotational stiffnesses.

11. The buckling-restrained brace out-of-plane stability design method considering a bidirectional seismic action according to claim 3, wherein the application of the design method needs to meet the following two conditions: the buckling-restrained brace subsystem meets a symmetric analysis model, and a main beam of a frame does not undergo a torsion deformation under the bidirectional seismic action, wherein in the symmetric analysis model, an upper connecting segment and a lower connecting segment of the buckling-restrained brace are equal in length, the upper connecting segment and the lower connecting segment have equal out-of-plane flexural stiffnesses, and the two gusset plates connected up and down have equal out-of-plane rotational stiffnesses.

12. The buckling-restrained brace out-of-plane stability design method considering a bidirectional seismic action according to claim 4, wherein the application of the design method needs to meet the following two conditions: the buckling-restrained brace subsystem meets a symmetric analysis model, and a main beam of a frame does not undergo a torsion deformation under the bidirectional seismic action, wherein in the symmetric analysis model, an upper connecting segment and a lower connecting segment of the buckling-restrained brace are equal in length, the upper connecting segment and the lower connecting segment have equal out-of-plane flexural stiffnesses, and the two gusset plates connected up and down have equal out-of-plane rotational stiffnesses.

13. The buckling-restrained brace out-of-plane stability design method considering a bidirectional seismic action according to claim 5, wherein the application of the design method needs to meet the following two conditions: the buckling-restrained brace subsystem meets a symmetric analysis model, and a main beam of a frame does not undergo a torsion deformation under the bidirectional seismic action, wherein in the symmetric analysis model, an upper connecting segment and a lower connecting segment of the buckling-restrained brace are equal in length, the upper connecting segment and the lower connecting segment have equal out-of-plane flexural stiffnesses, and the two gusset plates connected up and down have equal out-of-plane rotational stiffnesses.

14. The buckling-restrained brace out-of-plane stability design method considering a bidirectional seismic action according to claim 6, wherein the application of the design method needs to meet the following two conditions: the buckling-restrained brace subsystem meets a symmetric analysis model, and a main beam of a frame does not undergo a torsion deformation under the bidirectional seismic action, wherein in the symmetric analysis model, an upper connecting segment and a lower connecting segment of the buckling-restrained brace are equal in length, the upper connecting segment and the lower connecting segment have equal out-of-plane flexural stiffnesses, and the two gusset plates connected up and down have equal out-of-plane rotational stiffnesses.

15. The buckling-restrained brace out-of-plane stability design method considering a bidirectional seismic action according to claim 7, wherein the application of the design method needs to meet the following two conditions: the buckling-restrained brace subsystem meets a symmetric analysis model, and a main beam of a frame does not undergo a torsion deformation under the bidirectional seismic action, wherein in the symmetric analysis model, an upper connecting segment and a lower connecting segment of the buckling-restrained brace are equal in length, the upper connecting segment and the lower connecting segment have equal out-of-plane flexural stiffnesses, and the two gusset plates connected up and down have equal out-of-plane rotational stiffnesses.

16. The buckling-restrained brace out-of-plane stability design method considering a bidirectional seismic action according to claim 8, wherein the application of the design method needs to meet the following two conditions: the buckling-restrained brace subsystem meets a symmetric analysis model, and a main beam of a frame does not undergo a torsion deformation under the bidirectional seismic action, wherein in the symmetric analysis model, an upper connecting segment and a lower connecting segment of the buckling-restrained brace are equal in length, the upper connecting segment and the lower connecting segment have equal out-of-plane flexural stiffnesses, and the two gusset plates connected up and down have equal out-of-plane rotational stiffnesses.
